(19) United States
(12) Patent Application Publication
(10) Pub. No.: US 2018/0359848 A1
(43) Pub. Date: Dec. 13, 2018

(54) PRINTED CIRCUIT BOARD FOR HIGH-SPEED TRANSMISSION

(71) Applicant: Accton Technology Corporation, Hsinchu City (TW)

(72) Inventor: Syue-Liang HONG, Pingtung City (TW)

(73) Assignee: Accton Technology Corporation, Hsinchu City (TW)

(21) Appl. No.: 15/845,463

(22) Filed: Dec. 18, 2017

(30) Foreign Application Priority Data
Jun. 13, 2017 (CN) 201720683727.3

(51) Int. Cl. H05K 1/02; H05K 1/18; H05K 1/11

(52) U.S. Cl. CPC H05K 1/0242; H05K 1/025; H05K 1/115; H05K 1/18

(57) ABSTRACT

A printed circuit board (PCB) for high-speed transmission is provided. The PCB includes: a plurality of circuit layers having one or more differential signal wires; a ground via, an anti-pad, and a signal via pair. The one or more differential signal wires have a first differential signal wire width on the plurality of circuit layers. The ground via provides a ground terminal to the plurality of circuit layers. The signal via pair is for connecting the plurality of circuit layers via a through-hole, so that the one or more differential signal wires pass through the anti-pad and pin through the plurality of circuit layers for signal transmission via the signal via pair. The one or more differential signal wires have a second differential signal wire width on the anti-pad, wherein the second differential signal wire width is greater than the first differential signal wire width.

### CROSS REFERENCE TO RELATED APPLICATIONS

This Application claims priority of China Patent Application No. 201720683727.3, filed on Jun. 13, 2017, the entirety of which is incorporated by reference herein.

### BACKGROUND OF THE INVENTION

### Field of the Invention

The present invention relates to a printed circuit board (PCB), and, in particular, to a printed circuit board for high-speed transmission.

### Description of the Related Art

Technological advancements have allowed the transmission speed of electronic communication devices to become much higher than in the past, with a high transmission speed of 100 Gbps, for example. For electronic devices that provide high-speed communication, the quality of the printed circuit board is very important and the layouts on the printed circuit board have a great impact on the stability of the signal transmission of these electronic communication devices.

The layout on a conventional multi-layer printed circuit board is usually not designed for high-speed data transmission, especially on the signal via of the printed circuit board. During high-speed data transmission, the differential pair of wires around the signal via may have discontinuous impedances, resulting in poor signal quality.

Accordingly, there is demand for a printed circuit board for high-speed transmission to solve the aforementioned problem.

### BRIEF SUMMARY OF THE INVENTION

A detailed description is given in the following embodiments with reference to the accompanying drawings.

In an exemplary embodiment, a printed circuit board (PCB) for high-speed transmission is provided. The PCB includes: a plurality of circuit layers having one or more differential signal wires; a ground via, an anti-pad, and a signal via pair. The one or more differential signal wires have a first differential signal wire width on the plurality of circuit layers. The ground via provides a ground terminal to the plurality of circuit layers. The signal via pair is for connecting the plurality of circuit layers via a through-hole, so that the one or more differential signal wires pass through the anti-pad and pin through the plurality of circuit layers for signal transmission via the signal via pair. The one or more differential signal wires have a second differential signal wire width on the anti-pad, wherein the second differential signal wire width is greater than the first differential signal wire width.

In another exemplary embodiment, a printed circuit board (PCB) for high-speed transmission is provided. The PCB includes: a plurality of circuit layers having one or more differential signal wires; a ground via, an anti-pad, and a signal via pair. The one or more differential signal wires have a first differential signal wire width on the plurality of circuit layers. The ground via provides a ground terminal to the plurality of circuit layers. The signal via pair is for connecting the plurality of circuit layers via a through-hole, so that the one or more differential signal wires pass through the anti-pad and pin through the plurality of circuit layers for signal transmission via the signal via pair. The one or more differential signal wires have a second differential signal wire width on the anti-pad. The first differential signal wire width on the top layer and the bottom layer is a first microstrip differential signal wire width, and the second differential signal wire width of the one or more differential signal wires that is overlapped with the anti-pad on the top layer and the bottom layer is a second microstrip differential signal wire width. The second microstrip differential signal wire width is greater than the first microstrip differential signal wire width.

In yet another exemplary embodiment, a printed circuit board (PCB) for high-speed transmission is provided. The PCB includes: a plurality of circuit layers having one or more differential signal wires; a ground via, an anti-pad, and a signal via pair. The one or more differential signal wires have a first differential signal wire width on the plurality of circuit layers. The ground via provides a ground terminal to the plurality of circuit layers. The signal via pair is for connecting the plurality of circuit layers via a through-hole, so that the one or more differential signal wires pass through the anti-pad and pin through the plurality of circuit layers for signal transmission via the signal via pair. The one or more differential signal wires have a second differential signal wire width on the anti-pad. The first differential signal wire width on the plurality of interior layers is a first stripline differential signal wire width, and the second differential signal wire width of the one or more differential signal wires that is overlapped with the anti-pad on the plurality of interior layers is a second stripline differential signal wire width, and the second stripline differential signal wire width is greater than the first stripline differential signal wire width, wherein the second stripline differential signal wire width is greater than the first stripline differential signal wire width.

### BRIEF DESCRIPTION OF THE DRAWINGS

The present invention can be more fully understood by reading the subsequent detailed description and examples with references made to the accompanying drawings, wherein:

FIG. 1A is a side view of a printed circuit board in accordance with an embodiment of the invention;

FIG. 1B is a diagram of the microstrip wires on the circuit layer 1 of the PCB in accordance with an embodiment of the invention;

FIG. 1C is a diagram of the stripline wires on the circuit layer 20 of the PCB in accordance with an embodiment of the invention;

FIG. 2A is a top view of the original structure of the printed circuit board in accordance with an embodiment of the invention;

FIG. 2B is a top view of a pin-hole model in the original structure of the printed circuit board in accordance with an embodiment of the invention;

FIG. 2C is a top view of the optimized structure of the printed circuit board in accordance with an embodiment of the invention;

FIG. 2D is a top view of a pin-hole model in the optimized structure of the printed circuit board in accordance with an embodiment of the invention;

FIG. 3A is a top view of the original structure of the printed circuit board in accordance with another embodiment of the invention;

FIG. 3B is a top view of a pin-hole model in the original structure of the printed circuit board in accordance with another embodiment of the invention;

FIG. 3C is a top view of the optimized structure of the printed circuit board in accordance with another embodiment of the invention;

FIG. 3D is a top view of a pin-hole model in the optimized structure of the printed circuit board in accordance with another embodiment of the invention;

FIG. 4A is a top view of the original structure of the printed circuit board in accordance with yet another embodiment of the invention;

FIG. 4B is a top view of a pin-hole model in the original structure of the printed circuit board in accordance with yet another embodiment of the invention;

FIG. 4C is a top view of the optimized structure of the printed circuit board in accordance with yet another embodiment of the invention;

FIG. 4D is a top view of a pin-hole model in the optimized structure of the printed circuit board in accordance with yet another embodiment of the invention;

FIG. 5A is a top view of the original structure of the printed circuit board in accordance with yet another embodiment of the invention;

FIG. 5B is a top view of a pin-hole model in the original structure of the printed circuit board in accordance with yet another embodiment of the invention;

FIG. 5C is a top view of the optimized structure of the printed circuit board in accordance with yet another embodiment of the invention; and

FIG. 5D is a top view of a pin-hole model in the optimized structure of the printed circuit board in accordance with yet another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

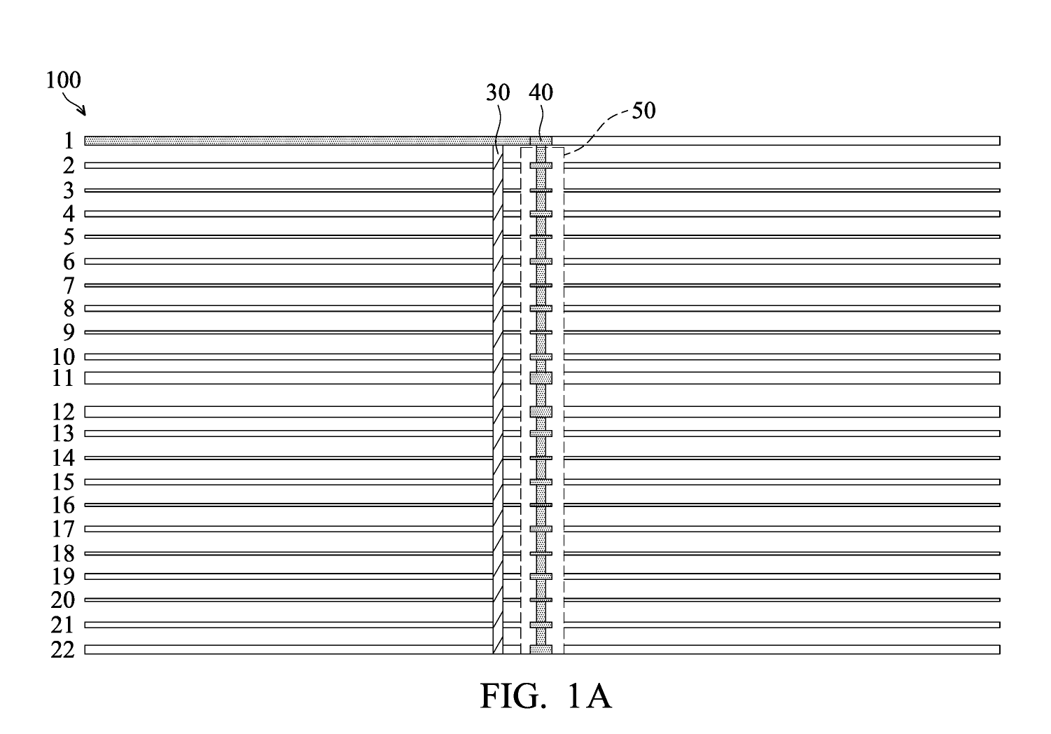

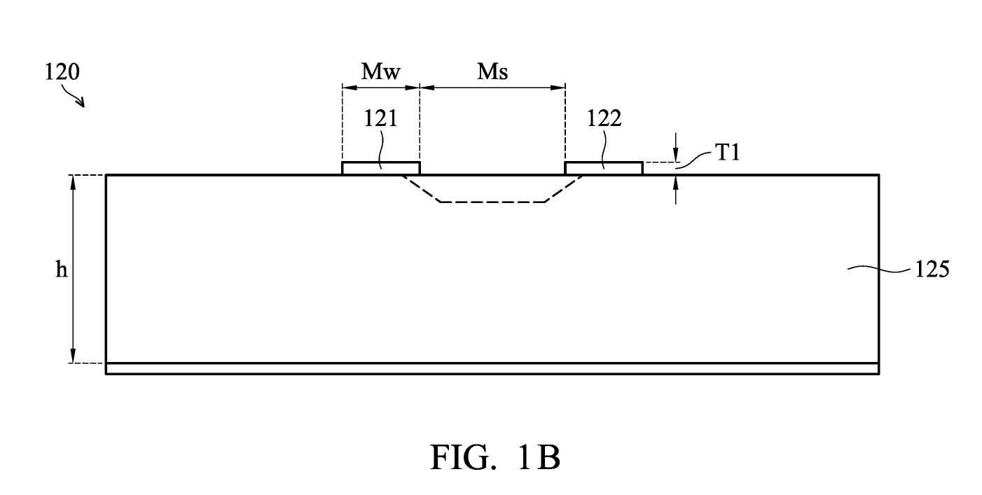

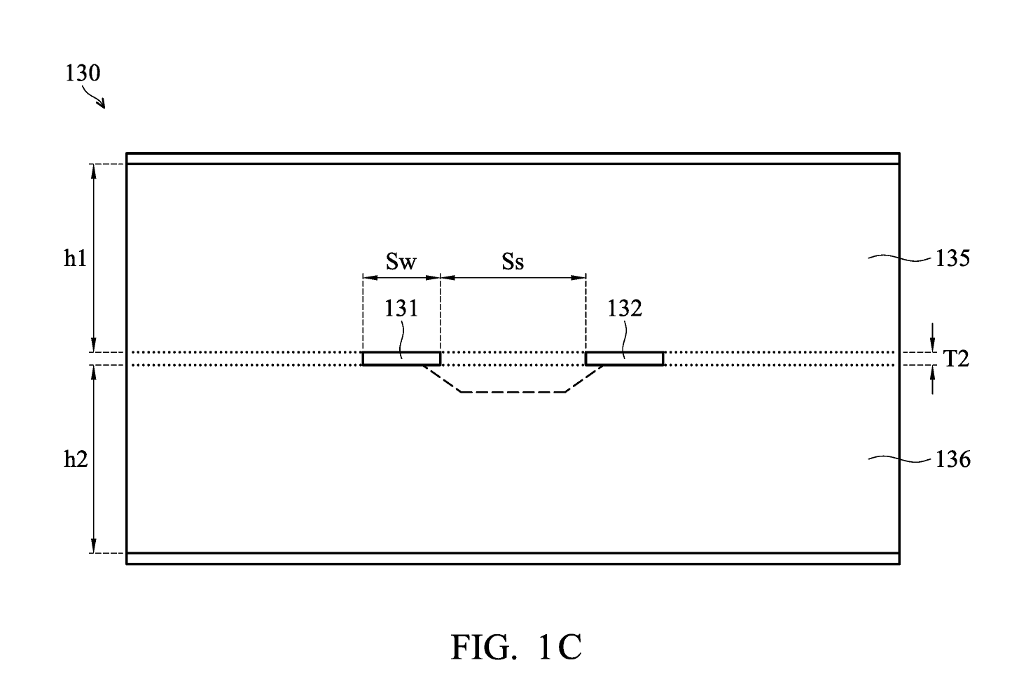

FIG. 1A is a side view of a printed circuit board in accordance with an embodiment of the invention. As illustrated in FIG. 1A, the printed circuit board 100 includes a plurality of circuit layers 1-22, a ground via 30, a signal via 40, and an anti-pad 50. The layout of the circuits on the PCB 100 are separated to the circuit layers 1-22, and the ground via 30 provides a ground for each of the circuit layers 1-22. The signal via is made of a conductive material that pins through the circuit layers 1-22, and the differential signal wire pair may be connected to different circuit layers through the signal via 40 according to the layout design. The number of circuit layers of the PCB 100 (e.g. 22 circuit layers) is for purposes of description, and the number of circuit layers of the PCB is not limited to the aforementioned number.

The characteristic impedance of the PCB corresponds to the layout design and wire routing. For example, the primary factors that affect the characteristic impedance of the wires on the PCB are: the width and thickness of the printed copper wires, the dielectric constant and thickness of the dielectric, the thickness of the PCB pad, path of the grounded wires, and wire routing. When the transmission speed of the signal on the printed wires exceeds 100 MHz, the printed wires can be regarded as wires having parasite capacitances and electrical inductances. In addition, a skin effect and loss of the dielectric may occur on the PCB in a high transmission speed, and the characteristic impedance of the transmission wires may also be affected by these factors. Based on the structure of transmission wires, there are two types of transmission wires such as microstrip wires and stripline wires. Generally, in the embodiment of FIG. 1A, there are 22 circuit layers in the PCB 100, and the microstrip wires can be used on the top layer 1 and the bottom layer 22, and the stripline wires can be used on the interior circuit layers 2-21 of the PCB 100, thereby preventing electromagnetic interferences.

Referring to FIG. 1A, an input signal is sent to the microstrip wires on the top circuit layer 1, and the input signal is transmitted to the stripline wires on the circuit layer 20 through the signal via 40.

FIG. 1B is a diagram of the microstrip wires on the circuit layer 1 of the PCB in accordance with an embodiment of the invention. In an embodiment, the circuit layer 1 can be implemented by the microstrip structure. That is, a specific printed copper wire may form a microstrip wire having an electrical inductance, allowing the high-frequency signal being effectively transmitted on the PCB 100. The microstrip structure may also form a match network with other components such as electrical inductors or capacitors, so that the signal output terminal may well match the load.

As illustrated in FIG. 1B, the thickness of the dielectric layer 125 of the microstrip structure 120 is h, and the dielectric constant of the dielectric layer 125 is ϵᵣ. The differential signal wires 121 and 122 have a “microstrip differential signal wire width” Mw and a “microstrip differential signal wire thickness” T1, and the distance between two differential signal wires is Ms.

FIG. 1C is a diagram of the stripline wires on the circuit layer 20 of the PCB in accordance with an embodiment of the invention.

As illustrated in FIG. 1C, the thickness of the upper dielectric layer 135 is h1, and the dielectric constant of the upper dielectric layer 135 is ϵᵣ₁. The thickness of the bottom dielectric layer 136 is h2, and the dielectric constant of the bottom dielectric layer 136 is ϵᵣ₂. The differential signal wires 131 and 132 in the stripline structure 130 have a “stripline differential signal wire width” Sw and a “stripline differential signal wire thickness” T2, and the distance between two differential signal wires is Ss. Accordingly, the overall thickness of the stripline structure 130 is (h1+h2+T2).

It should be noted that the differential signal wires 121 and 122 in the microstrip structure 120 of the circuit layer 1 are respectively connected to the differential signal wires 131 and 132 in the stripline structure 130 of the circuit layer 20 through the signal via 40.

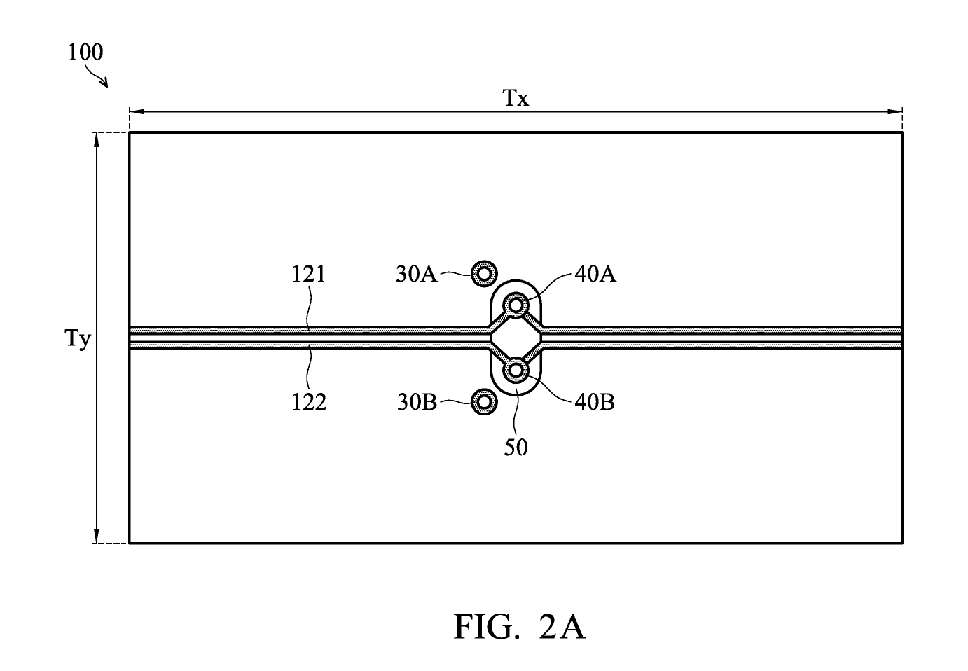

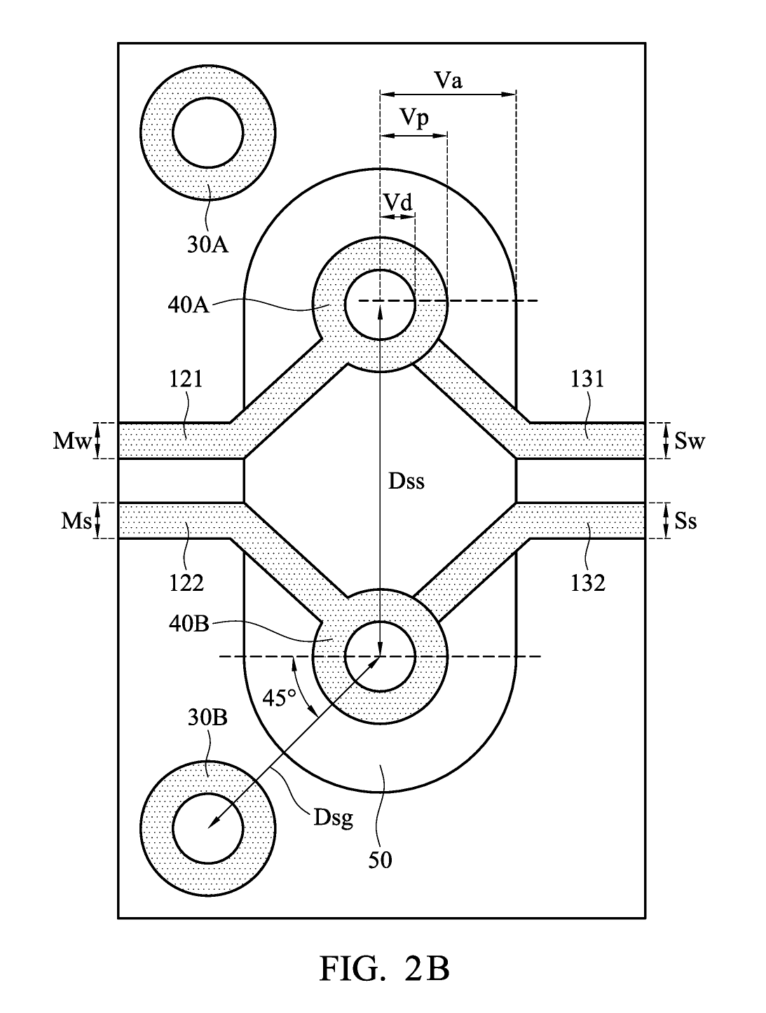

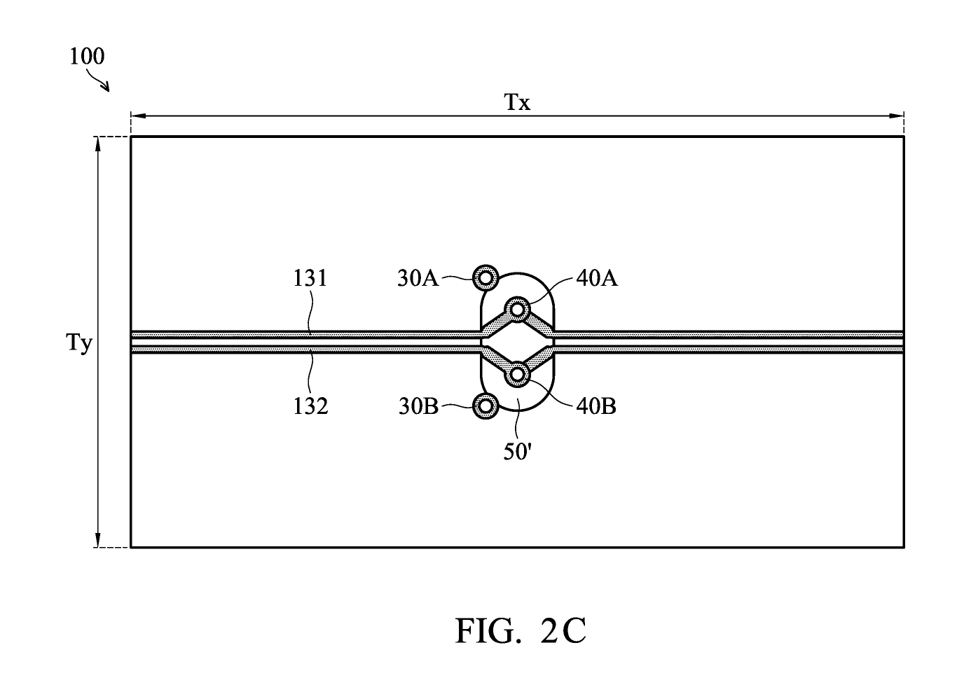

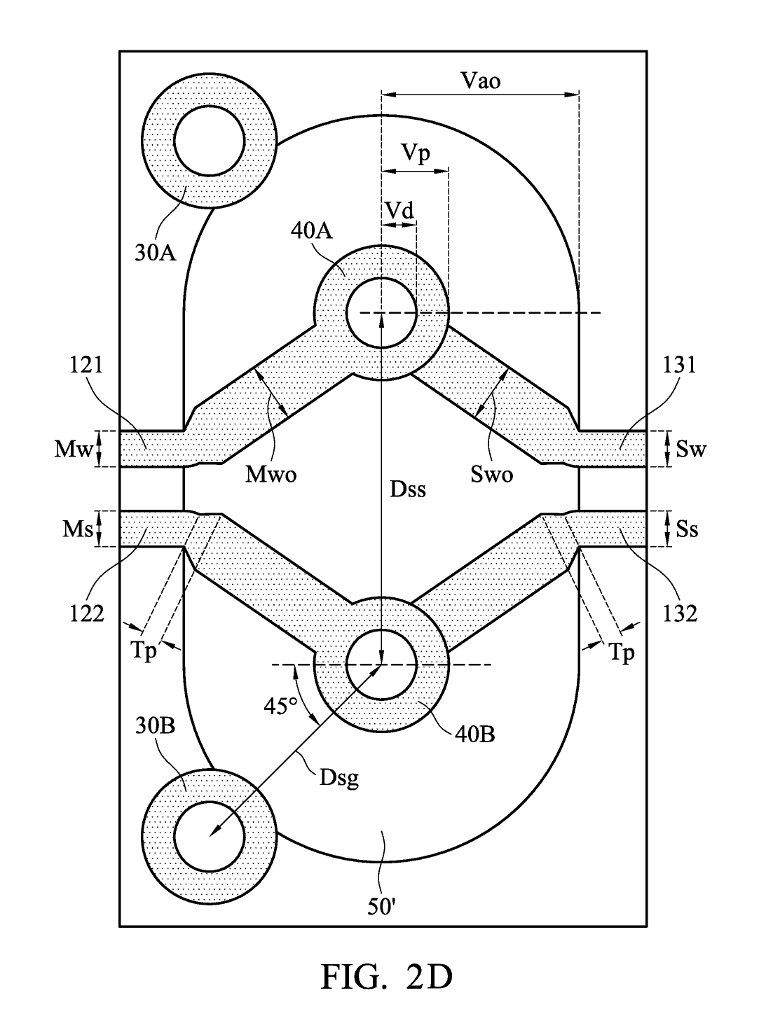

FIG. 2A is a top view of the original structure of the printed circuit board in accordance with an embodiment of the invention. FIG. 2B is a top view of a pin-hole model in the original structure of the printed circuit board in accordance with an embodiment of the invention. Referring to FIG. 2A and FIG. 2B, the PCB 100 has a length Tx and a width Ty. FIG. 2B illustrates the top view around the pin-hole model around the anti-pad 50 in FIG. 2A, wherein the anti-pad 50 in FIG. 2A and FIG. 2B has the shape of an ellipse.

Referring to FIG. 1A, the signal via 40 is capable of transmitting differential signals, and the ground via 30 provides a ground terminal to each circuit layer of the PCB 100. Referring to FIG. 2A and FIG. 2B, the signal via 40 can be classified into a signal vias 40A and 40B that have a pin-hole-radius Vd, and the radius of the via pad is Vp. In addition, the anti-pad 50 corresponding to the signal vias 40A and 40B has a radius Va.

The ground via 30 can be classified into ground vias 30A and 30B. The distance between the signal vias 40A and 40B is Dss, and the distance between the signal via 40A and the ground via 30A is Dsg. The distance between the signal via 40B and the ground via 40B is also Dsg.

FIG. 2C is a top view of the optimized structure of the printed circuit board in accordance with an embodiment of the invention. FIG. 2D is a top view of a pin-hole model in the optimized structure of the printed circuit board in accordance with an embodiment of the invention.

In an embodiment, the original structure having an ellipse-shaped anti-pad in FIGS. 2A and 2B is optimized. For example, the size of the anti-pad 50 close to the signal vias 40A and 40B is increased, such as increasing the radius of the anti-pad 50 to Vao, as illustrated in FIG. 2C. Thus, the capacitance between the signal vias 40A and 40B and their neighboring reference planes (e.g. circuit layers) can be reduced, and the impedance of the signal vias 40A and 40B are also improved, thereby achieving impedance matching. However, the connection portion between the differential signal wires and corresponding signal vias may have a high impedance due to the enlarged size of the anti-pad 50, so that the condition of impedance unmatching may happen when the transmission signal passes through connection portion having a high impedance. In order to improve the signal quality, the width of the differential signal wires on the anti-pad around the corresponding signal vias is also increased, so that the impedance of the connection portion can be reduced, thereby achieving impedance matching.

As illustrated in FIG. 2D, in the optimized structure, the microstrip differential signal wire 121 (or 122) has a width Mwo at the region around the signal via 40A and overlapped with the anti-pad 50, and the width can be regarded as a “connection-portion microstrip differential signal wire width”. In addition, the length of the tapered portion of the microstrip differential signal wires 121 and 122 is Tp. In an embodiment, Mwo=2Mw. That is, the wire width of the microstrip differential signal wire 121 is doubled on the connection portion with the signal via 40A (i.e. the overlapped region within the radius of the anti-pad 50′), thereby reducing the impedance of the connection portion and achieving impedance matching. It should be noted that the microstrip structure of the circuit layer 1 is used in the aforementioned embodiment.

Similarly, in the optimized structure, the stripline differential signal wire 131 (or 132) has a width Swo at the region around the signal via 40A and overlapped with the anti-pad 50, and the width can be regarded as a “connection-portion stripline differential signal wire width”. In addition, the length of the tapered portion of the stripline differential signal wires 121 and 122 is Tp. In an embodiment, Swo=2Sw. That is, the wire width of the stripline differential signal wire 121 is doubled on the connection portion with the signal via 40A (i.e. the overlapped region within the radius of the anti-pad 50′), thereby reducing the impedance of the connection portion and achieving impedance matching. It should be noted that the stripline structure of the circuit layer 20 is used in the aforementioned embodiment.

It should be noted that the increment ratio of the widths of the microstrip differential signal wire (i.e. Mwo) and the stripline differential signal wire (i.e. Swo) in the optimized structure relative to the widths of the microstrip differential signal wire (i.e. Mw) and the stripline differential signal wire (i.e. Sw) in the original structure can be adjusted according to the practical layout of the PCB.

Table 1 illustrates various parameters of the PCB 100 in FIGS. 2A˜2D.

TABLE 1

| Parameter | Value | Parameter | Value |
|---|---|---|---|
| Tx | 640 mil | h2 | 4.3 mil |
| Ty | 320 mil | Dss | 50 mil |
| Va | 20 mil | Dsg | 35 mil |
| Vp | 10 mil | Mw | 5 mil |
| Vd | 5 mil | Ms | 7 mil |
| Tp | 4 mil | Sw | 4.5 mil |
| T1 | 2 mil | Ss | 8.5 mil |
| T2 | 0.6 mil | Vao | 30 mil |
| h | 3.8 mil | Mwo | 2 * Mw |
| h1 | 4.4 mil | Swo | 2 * Sw |

In Table 1, a “mil” denotes 0.001 inch. The values of the parameters in Table 1 are for purposes of description, but the invention is not limited thereto.

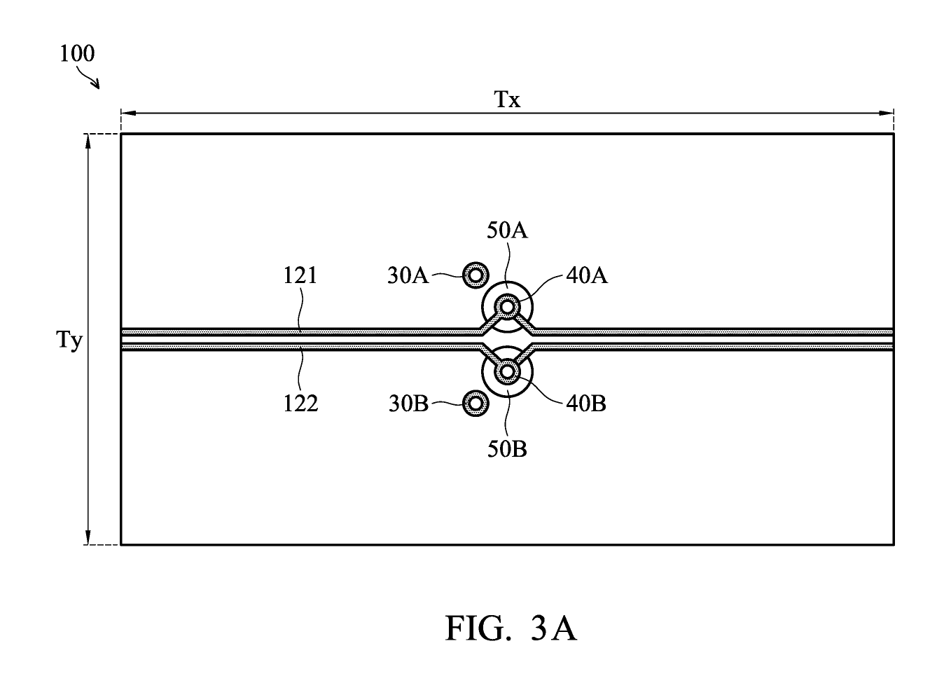

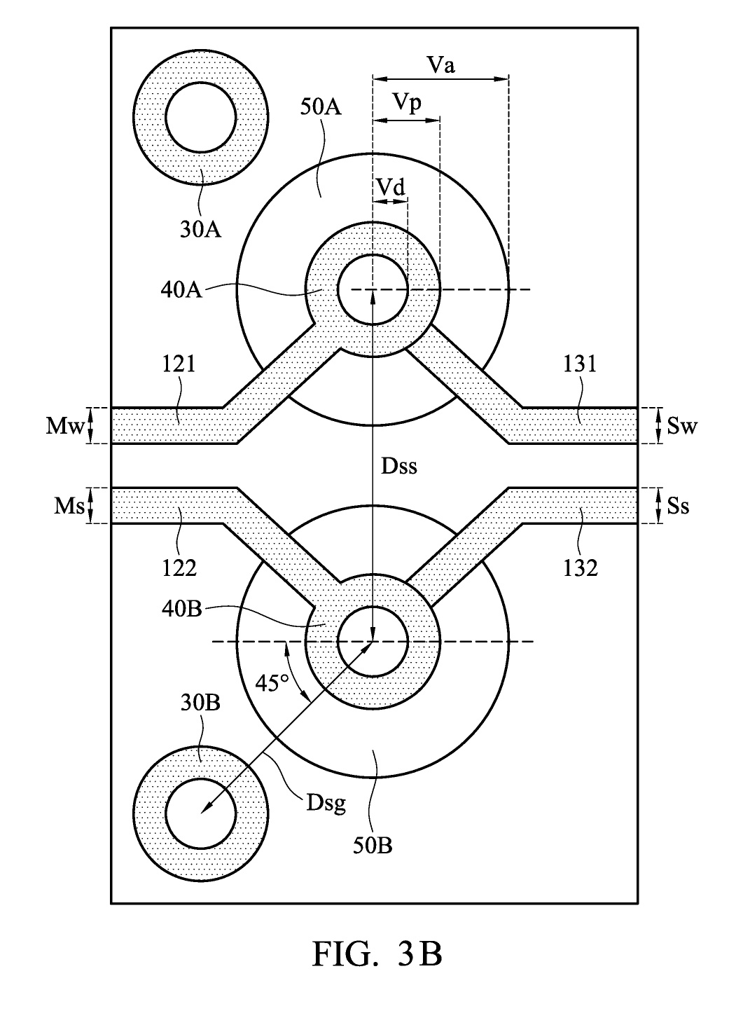

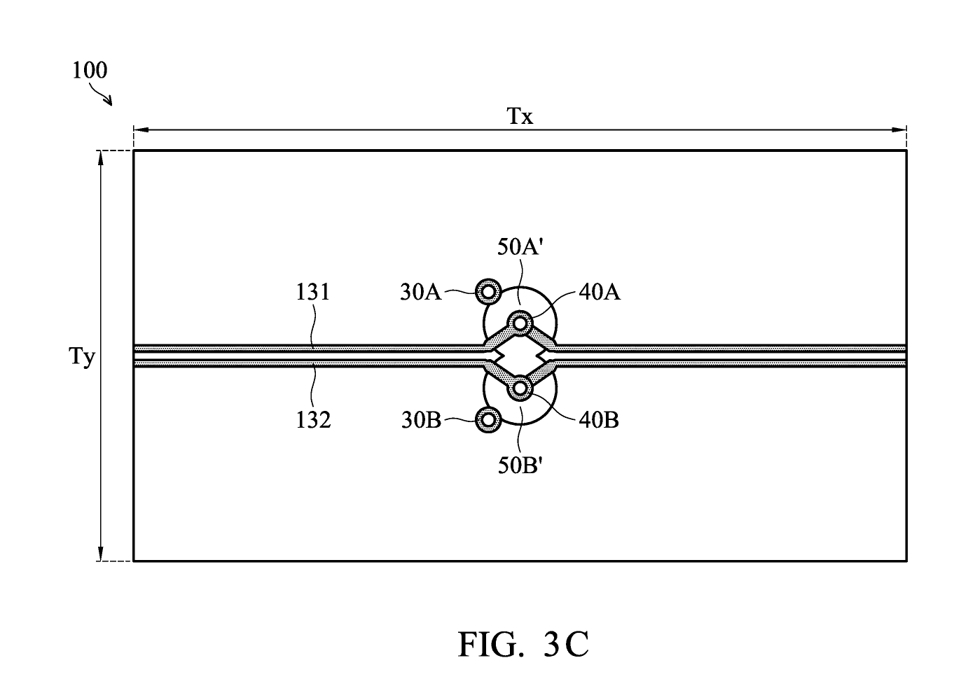

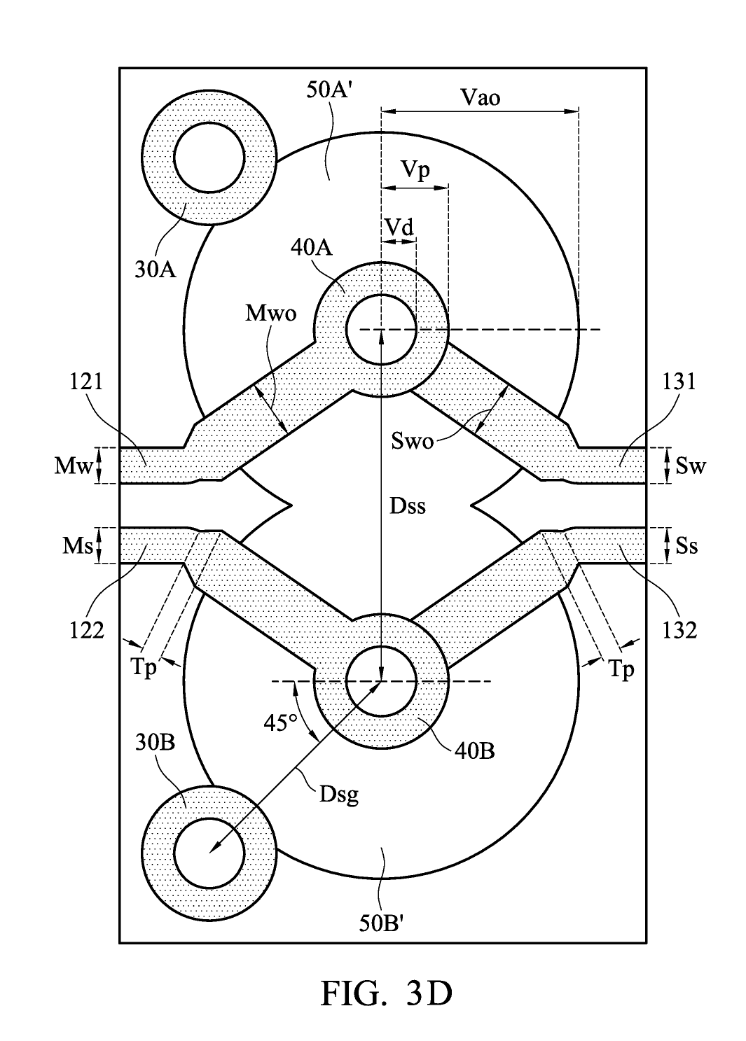

FIG. 3A is a top view of the original structure of the printed circuit board in accordance with another embodiment of the invention. FIG. 3B is a top view of a pin-hole model in the original structure of the printed circuit board in accordance with another embodiment of the invention. FIG. 3C is a top view of the optimized structure of the printed circuit board in accordance with another embodiment of the invention. FIG. 3D is a top view of a pin-hole model in the optimized structure of the printed circuit board in accordance with another embodiment of the invention.

In some embodiments, the anti-pad 50 associated with the signal vias 40A and 40B may have the shape of a circle, and the circle-shaped anti-pad is illustrated in the embodiments of FIGS. 3A˜3D. The difference between FIGS. 3A˜3D and 2A˜2D is that each of the signal vias 40A and 40B has a respective circle-shaped anti-pad, such as anti-pads 50A and 50B. The parameters of the original structure and the optimized structure using the circle-shaped anti-pad in FIGS. 3B and 3D are similar to those in FIG. 2B and 2D, and thus the details will be omitted here.

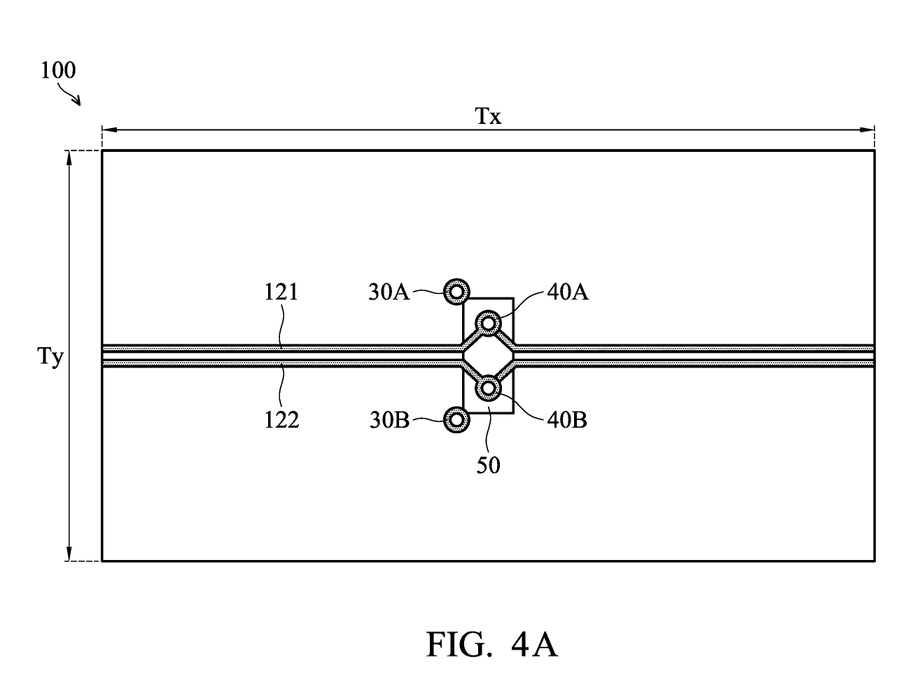

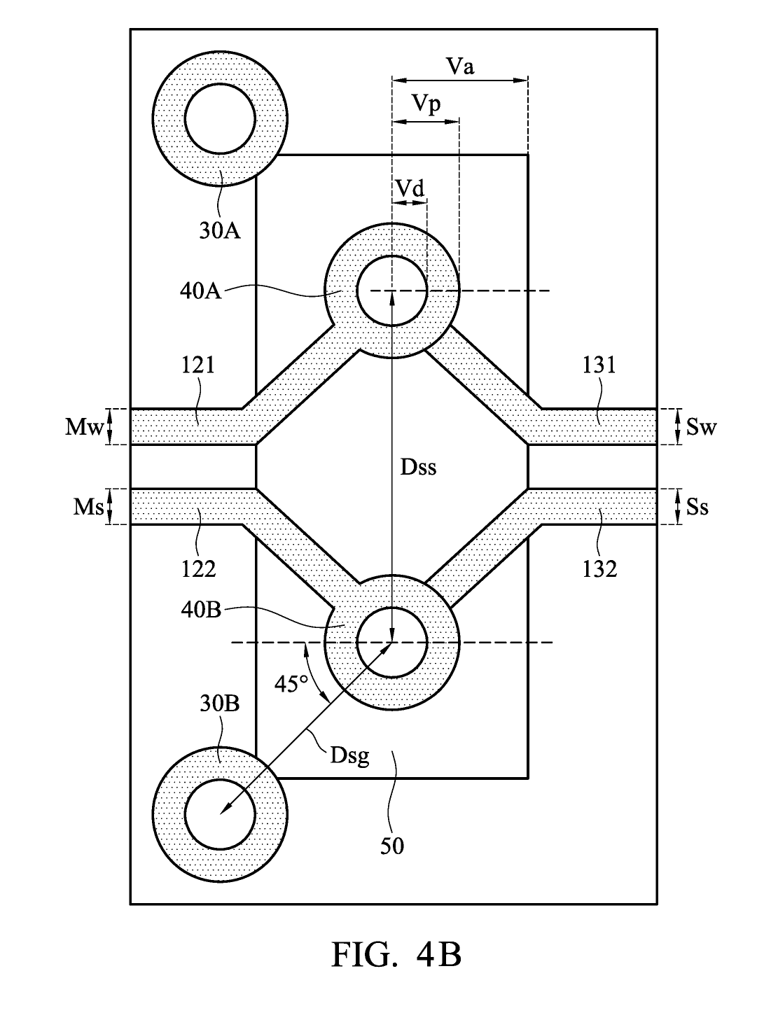

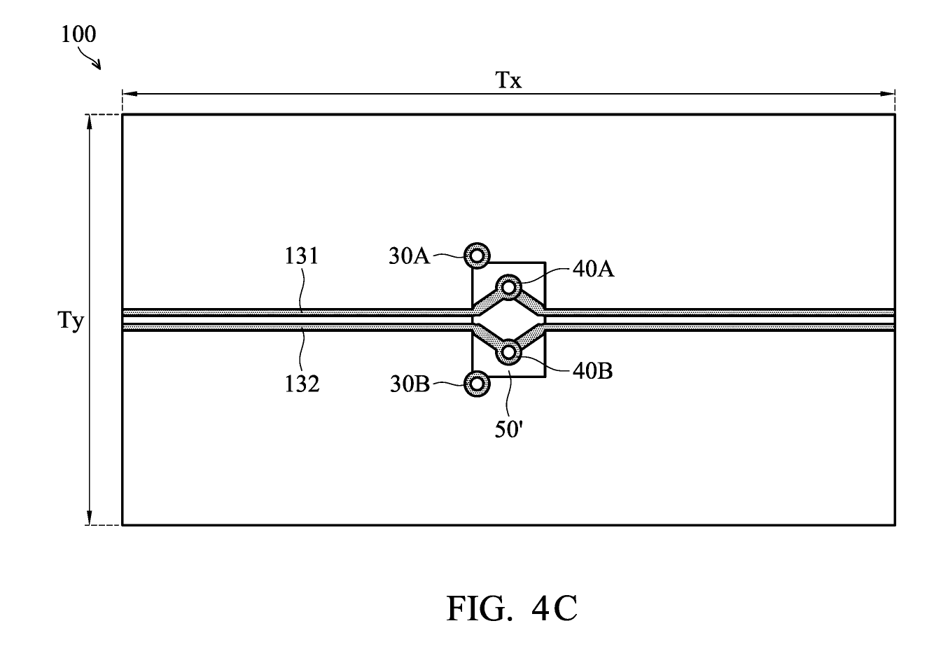

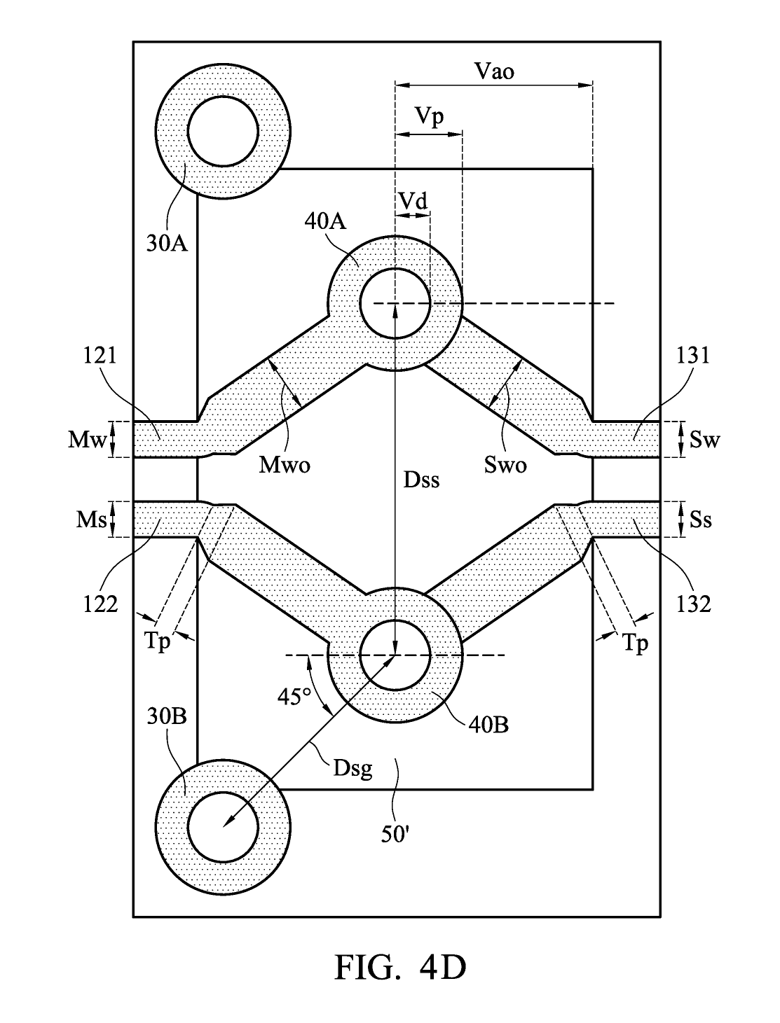

FIG. 4A is a top view of the original structure of the printed circuit board in accordance with yet another embodiment of the invention. FIG. 4B is a top view of a pin-hole model in the original structure of the printed circuit board in accordance with yet another embodiment of the invention. FIG. 4C is a top view of the optimized structure of the printed circuit board in accordance with yet another embodiment of the invention. FIG. 4D is a top view of a pin-hole model in the optimized structure of the printed circuit board in accordance with yet another embodiment of the invention.

In some embodiments, the anti-pad 50 associated with the signal vias 40A and 40B may have the shape of a rectangle, and the rectangular-shaped anti-pad is illustrated in the embodiments of FIGS. 4A˜4D. The difference between FIGS. 4A˜4D and 2A˜2D is that the signal vias 40A and 40B correspond to the rectangular-shaped anti-pad 50. The parameters of the original structure and the optimized structure using the circle-shaped anti-pad in FIGS. 4B and 4D are similar to those in FIG. 2B and 2D, and thus the details will be omitted here.

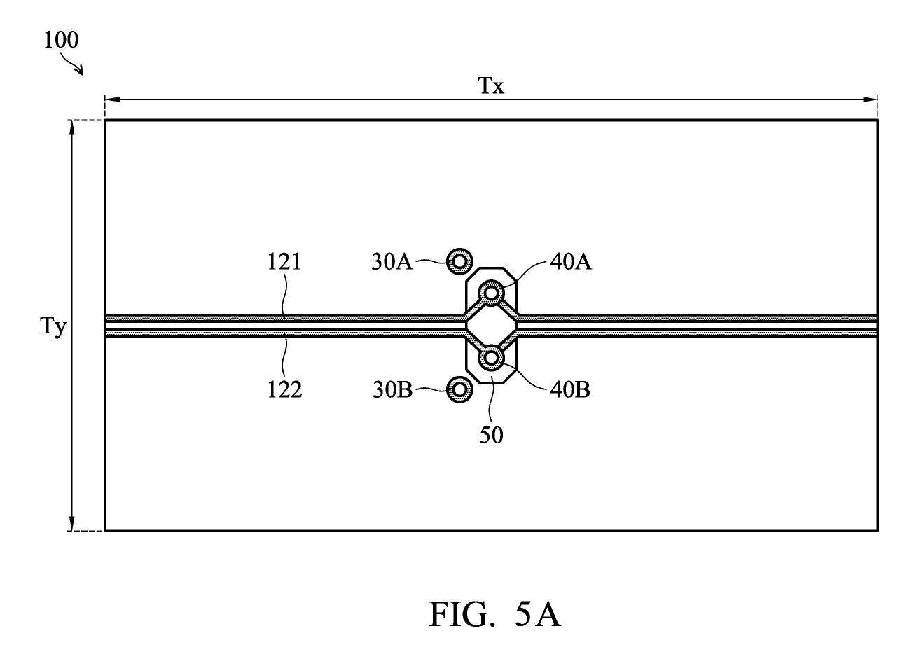

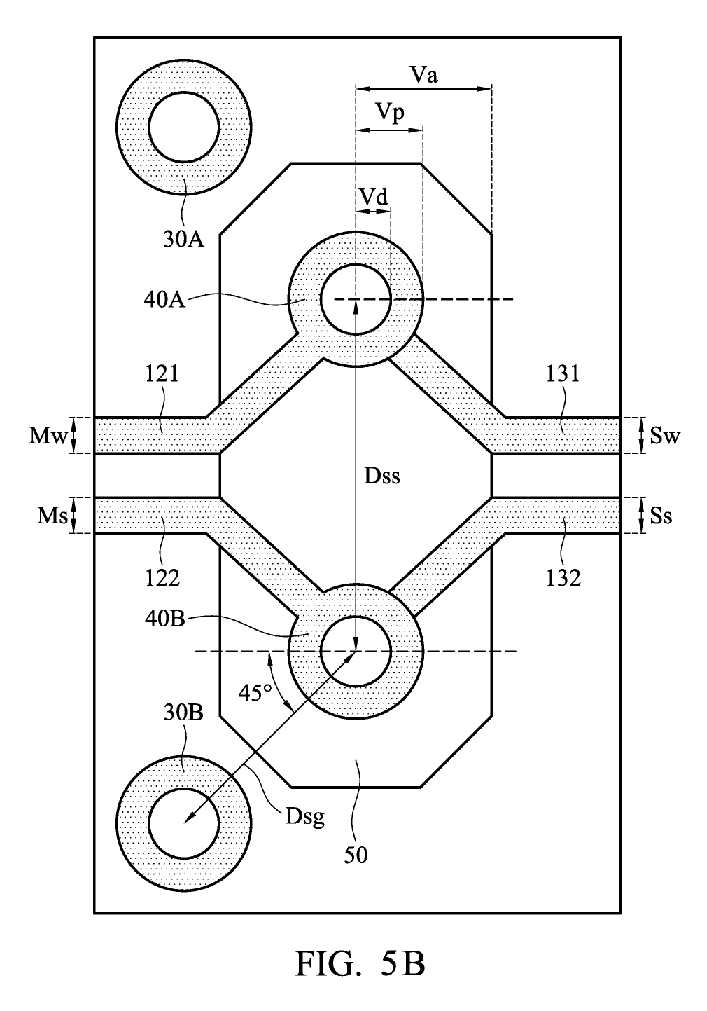

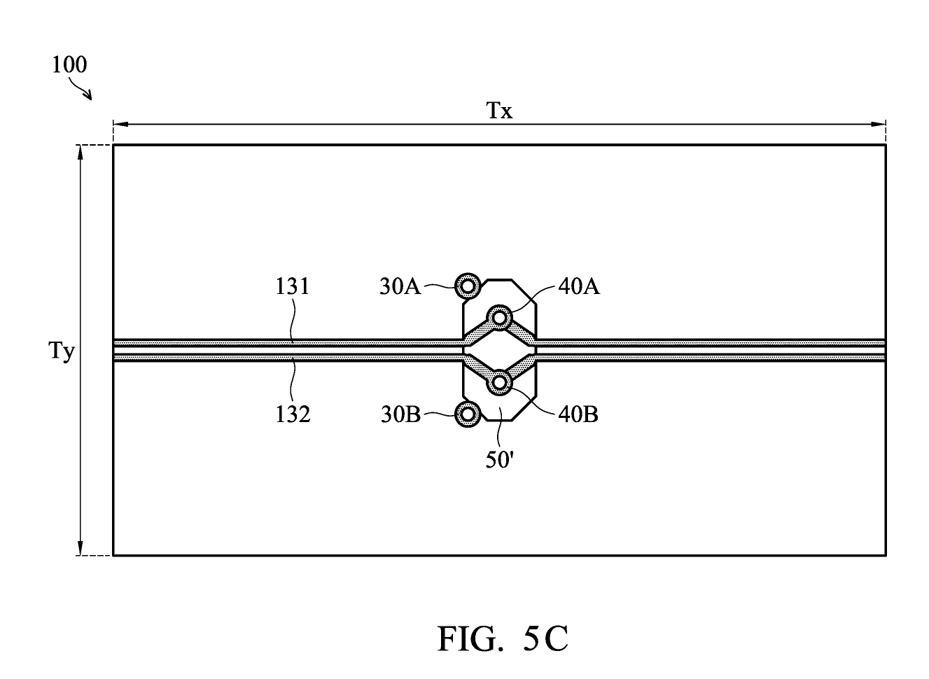

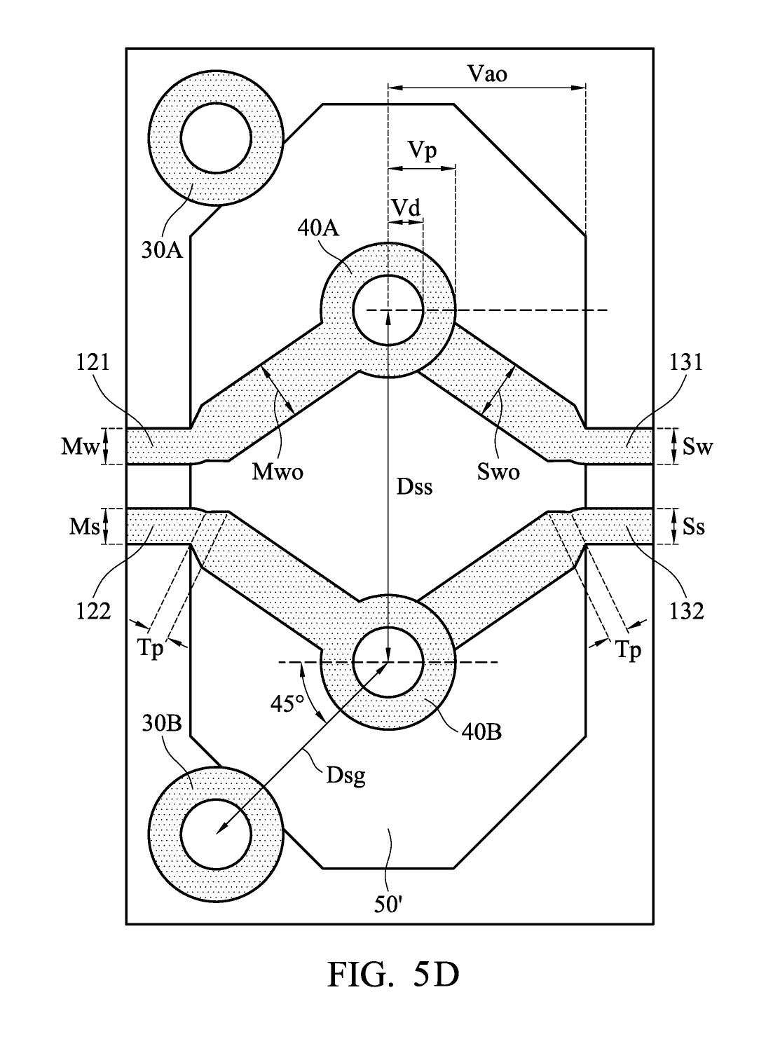

FIG. 5A is a top view of the original structure of the printed circuit board in accordance with yet another embodiment of the invention. FIG. 5B is a top view of a pin-hole model in the original structure of the printed circuit board in accordance with yet another embodiment of the invention. FIG. 5C is a top view of the optimized structure of the printed circuit board in accordance with yet another embodiment of the invention. FIG. 5D is a top view of a pin-hole model in the optimized structure of the printed circuit board in accordance with yet another embodiment of the invention.

In some embodiments, the anti-pad 50 associated with the signal vias 40A and 40B may have the shape of a polygon, and the polygon-shaped anti-pad is illustrated in the embodiments of FIGS. 5A˜5D. The difference between FIGS. 5A˜5D and 2A˜2D is that the signal vias 40A and 40B correspond to the polygon-shaped anti-pad 50. The parameters of the original structure and the optimized structure using the circle-shaped anti-pad in FIGS. 5B and 5D are similar to those in FIGS. 2B and 2D, and thus the details will be omitted here.

It should be noted that the shape of the anti-pad of the PCB is not limited to a ellipse, a circle, a rectangle, or a polygon, and can be adjusted according to practical situations. For example, the anti-pad on the PCB may have different shapes when being manufactured by different manufacturers. No matter which shape of the anti-pad is, the width of the differential signal wires and the size of the anti-pad can be adjusted correspondingly on the connection portion between the differential signal wires and the signal vias (i.e. the overlapped region within the radius of the anti-pad). For example, the size of the anti-pad in different shapes can be enlarged, and the width of the differential signal wires is also increased in the overlapped region within the radius of the anti-pad.

In view of the above, a printed circuit board for high-speed transmission is provided. The size of the anti-pad and the width of the differential signal wires of the printed circuit board can be increased, so that the problem of the discontinuous impedance caused by a high-frequency signal on the connection portion in the conventional printed circuit board can be solved. In addition, the high-frequency signal may have a lower impedance on the connection portion using the printed circuit board of the invention, thereby achieving impedance matching and improving the signal quality.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A printed circuit board for high-speed transmission, comprising:
a plurality of circuit layers, comprising one or more differential signal wires, wherein the one or more differential signal wires have a first differential signal wire width on the plurality of circuit layers;
a ground via, for providing a ground terminal to the plurality of circuit layers;
an anti-pad; and
a signal via pair, for connecting the plurality of circuit layers via a through-hole, so that the one or more differential signal wires pass through the anti-pad and pin through the plurality of circuit layers for signal transmission via the signal via pair,
wherein the one or more differential signal wires have a second differential signal wire width on the anti-pad,
wherein the second differential signal wire width is greater than the first differential signal wire width.

2. The printed circuit board as claimed in claim 1, wherein the anti-pad has a shape of an ellipse, a circle, a rectangle, or a polygon.

3. The printed circuit board as claimed in claim 1, wherein the plurality of circuit layers comprises a top layer, a bottom layer, and a plurality of interior layers, wherein the a microstrip structure is used on the top layer and the bottom layer, and a stripline structure is used on the plurality of interior layers.

4. The printed circuit board as claimed in claim 3, wherein the first differential signal wire width on the top layer and the bottom layer is a first microstrip differential signal wire width, and the second differential signal wire width of the one or more differential signal wires that is overlapped with the anti-pad on the top layer and the bottom layer is a second microstrip differential signal wire width.

5. The printed circuit board as claimed in claim 3, wherein the first differential signal wire width on the plurality of interior layers is a first stripline differential signal wire width, and the second differential signal wire width of the one or more differential signal wires that is overlapped with the anti-pad on the plurality of interior layers is a second stripline differential signal wire width.

6. The printed circuit board as claimed in claim 1, wherein the anti-pad has a first radius, and another anti-pad in a printed circuit board that is not for high-speed transmission has a second radius, and the first radius is greater than the second radius.

7. A printed circuit board for high-speed transmission, comprising:
a plurality of circuit layers, comprising one or more differential signal wires, wherein the one or more differential signal wires have a first differential signal wire width on the plurality of circuit layers, wherein the plurality of circuit layers comprises a top layer, a bottom layer, and a plurality of interior layers, wherein the a microstrip structure is used on the top layer and the bottom layer, and a stripline structure is used on the plurality of interior layers;
a ground via, for providing a ground terminal to the plurality of circuit layers;
an anti-pad; and
a signal via pair, for pinning through the plurality of circuit layers, so that the one or more differential signal wires pass through the anti-pad and pin through the plurality of circuit layers for signal transmission via the signal via pair,
wherein the one or more differential signal wires have a second differential signal wire width on the anti-pad,
wherein the first differential signal wire width on the top layer and the bottom layer is a first microstrip differential signal wire width, and the second differential signal wire width of the one or more differential signal wires that is overlapped with the anti-pad on the top layer and the bottom layer is a second microstrip differential signal wire width,
wherein the second microstrip differential signal wire width is greater than the first microstrip differential signal wire width.

8. The printed circuit board as claimed in claim 7, wherein the anti-pad has the shape of an ellipse, a circle, a rectangle, or a polygon.

9. The printed circuit board as claimed in claim 7, wherein the first differential signal wire width on the plurality of interior layers is a first stripline differential signal wire width, and the second differential signal wire width of the one or more differential signal wires that is overlapped with the anti-pad on the plurality of interior layers is a second stripline differential signal wire width, and the second stripline differential signal wire width is greater than the first stripline differential signal wire width.

10. A printed circuit board for high-speed transmission, comprising:
a plurality of circuit layers, comprising one or more differential signal wires, wherein the one or more differential signal wires have a first differential signal wire width on the plurality of circuit layers;
a ground via, for providing a ground terminal to the plurality of circuit layers;
an anti-pad; and
a signal via pair, for pinning through the plurality of circuit layers, so that the one or more differential signal wires pass through the anti-pad and pin through the plurality of circuit layers for signal transmission via the signal via pair,
wherein the one or more differential signal wires have a second differential signal wire width on the anti-pad,
wherein the first differential signal wire width on the plurality of interior layers is a first stripline differential signal wire width, and the second differential signal wire width of the one or more differential signal wires that is overlapped with the anti-pad on the plurality of interior layers is a second stripline differential signal wire width, and the second stripline differential signal wire width is greater than the first stripline differential signal wire width,
wherein the second stripline differential signal wire width is greater than the first stripline differential signal wire width.

11. The printed circuit board as claimed in claim 10, wherein the anti-pad has the shape of an ellipse, a circle, a rectangle, or a polygon.

12. The printed circuit board as claimed in claim 10, wherein the first differential signal wire width on the top layer and the bottom layer is a first microstrip differential signal wire width, and the second differential signal wire width of the one or more differential signal wires that is overlapped with the anti-pad on the top layer and the bottom layer is a second microstrip differential signal wire width, and the second microstrip differential signal wire width is greater than the first microstrip differential signal wire width.
